(19) United States
(12) Patent Application Publication
(10) Pub. No.: US 2026/0180575 A1
(43) Pub. Date: Jun. 25, 2026

(54) ELECTROSTATIC INPUT DEVICE WITH HIGH-ACCURACY POSITION DETECTION USING CAPACITANCE THRESHOLD RATIOS

(71) Applicant: ALPS ALPINE CO., LTD., Tokyo (JP)

(72) Inventor: Takashi FUJIKI, Miyagi (JP)

(21) Appl. No.: 19/423,328

(22) Filed: Dec. 17, 2025

Related U.S. Application Data
(63) Continuation of application No. PCT/JP2024/008549, filed on Mar. 6, 2024.

(30) Foreign Application Priority Data
Jul. 12, 2023 (JP) 2023-114743

(51) Int. Cl. H03K 17/96

(52) U.S. Cl. CPC H03K 17/9622; H03K 2217/96073; H03K 2217/960745

(57) ABSTRACT

An electrostatic input device includes sensor electrodes disposed corresponding to operation regions on an operation surface on which an operation input is performed, and a computer including a memory and a processor coupled to the memory. The computer is configured to compare capacitance threshold assigned to the sensor electrodes, respectively, with capacitance of the sensor electrodes, respectively, and check one or more sensor electrodes having the capacitance exceeding the capacitance threshold assigned to a corresponding sensor electrode. The computer is configured to, when the one or more sensor electrodes having the capacitance exceeding the capacitance threshold include two or more sensor electrodes adjacent to each other, identify, among the two or more sensor electrodes, the sensor electrode on which the operation input is performed based on a ratio between the capacitance of each of the two or more sensor electrodes and the capacitance threshold assigned to the corresponding sensor electrode.

### CROSS-REFERENCE TO RELATED APPLICATIONS

This application is a continuation application of International Application No. PCT/JP2024/008549, filed Mar. 6, 2024, which claims propriety to Japanese Patent Application No. 2023-114743 filed Jul. 12, 2023. The contents of these applications are incorporated herein by reference.

### BACKGROUND

### 1. Field of the Invention

The present invention relates to electrostatic input devices.

### 2. Description of the Related Art

There have been provided electrostatic input devices. The electrostatic input device includes a coordinate input unit, a capacitance measurement unit, and a control unit. In the coordinate input unit, a plurality of capacitance detection units are arranged in a matrix form, and an operator performs a proximity operation on the coordinate input unit. The capacitance measurement unit measures capacitance of each of the capacitance detection units and outputs the result as measurement signals. The control unit controls the capacitance measurement unit to acquire the measurement signals associated with the coordinate information of the capacitance detection units, computes the measurement signals, and outputs a control signal based on the computation result. The control unit sequentially determines the coordinates of interest according to the coordinate information of the capacitance detection units, compares the value of the measurement signal of the determined coordinates of interest with a plurality of values of the measurement signals of the coordinate information adjacent to the periphery of the coordinates of interest, and detects the coordinates of interest as the operation point on which the operator has performed the proximity operation, when the value of the measurement signal of the coordinates of interest is equal to or greater than the values of the measurement signals of the coordinate information adjacent to the periphery of the coordinates of interest (see, for example, Japanese Unexamined Patent Application Publication No. 2014-225057).

### SUMMARY

According to one aspect of the present disclosure, an electrostatic input device includes: a plurality of sensor electrodes disposed corresponding to a plurality of operation regions on an operation surface on which an operation input is performed; and a computer including a memory storing one or more programs and a processor coupled to the memory. The computer is configured to compare a plurality of capacitance thresholds, which are assigned to the plurality of sensor electrodes, respectively, with capacitance of the plurality of sensor electrodes, respectively, and check one or more sensor electrodes having the capacitance exceeding the capacitance threshold assigned to a corresponding sensor electrode. The computer is configured to, when the one or more sensor electrodes having the capacitance exceeding the capacitance threshold assigned to the corresponding sensor electrode include two or more sensor electrodes and the two or more sensor electrodes are adjacent to each other, identify, among the two or more sensor electrodes, the sensor electrode on which the operation input is performed based on a ratio between the capacitance of each of the two or more sensor electrodes and the capacitance threshold assigned to the corresponding sensor electrode.

### BRIEF DESCRIPTION OF THE DRAWINGS

FIG. 1 is a diagram illustrating an example of a configuration of the electrostatic input device of the present embodiment;

FIG. 2A is a view illustrating an example of a configuration of an operation unit of the electrostatic input device of the present embodiment;

FIG. 2B is a view illustrating an example of the configuration of the operation unit of the electrostatic input device of the present embodiment;

FIG. 3A is a diagram illustrating an example of a capacitance distribution of one sensor electrode, when a touch operation is separately performed on adjacent switches with a fingertip FT in a state in which gloves are worn;

FIG. 3B is a diagram illustrating an example of a capacitance distribution of another sensor electrode, when a touch operation is separately performed on adjacent switches with a fingertip in a state in which gloves are worn;

FIG. 4A is a diagram illustrating an example of a capacitance distribution of one sensor electrode, when a touch operation is separately performed on adjacent switches with a fingertip of a bare hand without wearing gloves;

FIG. 4B is a diagram illustrating an example of a capacitance distribution of another sensor electrode, when a touch operation is separately performed on adjacent switches with a fingertip of a bare hand without wearing gloves;

FIG. 5A is a diagram illustrating an overlapping area of the regions exceeding the thresholds in the capacitance distributions of the sensor electrodes of FIGS. 4A and 4B;

FIG. 5B is a diagram illustrating an overlapping area of the capacitance distributions of the adjacent sensor electrodes illustrated in FIGS. 4A and 4B;

FIG. 6A is a diagram illustrating a ratio of the capacitance (count value) illustrated in FIG. 5A to the threshold Thc of the sensor electrode 111A in percentage (%);

FIG. 6B is a diagram illustrating a ratio of the capacitance (count value) illustrated in FIG. 5B to the threshold Thc of the sensor electrode 112A in percentage (%); and

FIG. 7 is a diagram illustrating an example of a determination process executed by a control unit of the electrostatic input device of an embodiment.

### DETAILED DESCRIPTION

As being performed by the existing electrostatic input device, a determination method, in which whether a proximity operation (operation input) is performed on coordinates of interest is determined by comparing a value of a measurement signal of the coordinates of interest with values of measurement signals of peripheral coordinate information, may have difficulty in achieving a highly accurate determination.

Therefore, an object is to provide an electrostatic input device capable of highly accurately determining a position of an operation input.

Hereinafter, an embodiment to which the electrostatic input device of the present invention is applied will be described.

Hereinafter, the description will be given by defining an XYZ coordinate system. An X axis is an example of a first axis, a Y axis is an example of a second axis, and a Z axis is an example of a third axis. The direction parallel to the X axis (X direction), the direction parallel to the Y axis (Y direction), and the direction parallel to the Z axis (Z direction) are orthogonal to one another. In addition, a plan view refers to an XY plane view. In the following description, a length, a width, a thickness, or the like of each member may be exaggerated for facilitating the understanding of the configuration.

### Embodiments

### Configuration of Electrostatic Input Device 100

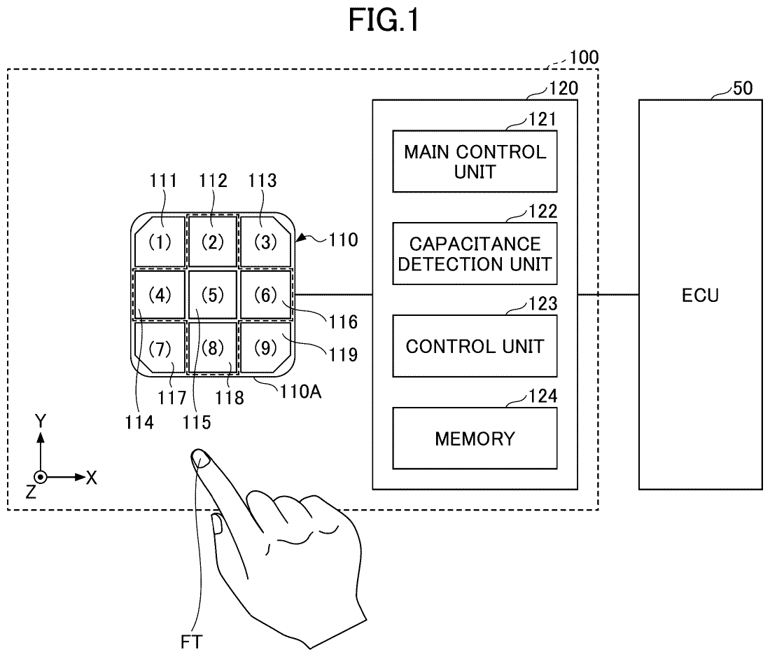

FIG. 1 is a diagram illustrating an example of a configuration of the electrostatic input device 100 of the embodiment. The electrostatic input device 100 includes an operation unit 110 and a control device 120. As an example, the operation unit 110 includes nine switches 111 to 119. The electrostatic input device 100 detects an operation input of a user to the switches 111 to 119, for example, with self-capacitance. Here, the regions in which the switches 111 to 119 are disposed, respectively, are denoted by (1) to (9).

Hereinafter, as an example, an embodiment in which an operation input performed by a user is a touch operation performed by touching any of the switches 111 to 119 with a fingertip FT will be described. However, the operation input may be an operation (hovering operation) of bringing the fingertip FT close to any of the switches 111 to 119 without touching. Moreover, a user may perform an operation input with a body part other than the fingertip FT (e.g., a part of a hand other than the fingertip).

Hereinafter, the embodiment in which as an example, the electrostatic input device 100 is mounted in a vehicle, and the switches 111 to 119 are used, for example, for operations of various electronic devices of the vehicle will be described.

By touching a portion of the surface of any of the switches 111 to 119 with the fingertip FT, a desired electronic device of the vehicle can be operated. A function of the electronic device operable by the switches 111 to 119 includes, for example, selection of audio, volume adjustment, selection of on-hook or termination of a hands-free phone, setting of cruise control, or the like. The vehicle is an automobile that can travel on a road using an engine, a motor, or both an engine and a motor, as a power source. The vehicle may be equipped with various levels of automated driving functions defined by, for example, Society of Automotive Engineers (SAE) International in the United States.

However, the electrostatic input device 100 may be mounted in an electronic device other than the electronic device mounted in the vehicle. For example, the electrostatic input device 100 may be a tablet input device or input unit of an automatic teller machine (ATM) that is disposed in a store, a facility, or the like, and is used by various unspecified users. Moreover, the electrostatic input device 100 may be a tablet computer, a smart phone, a game machine, or the like used by an individual.

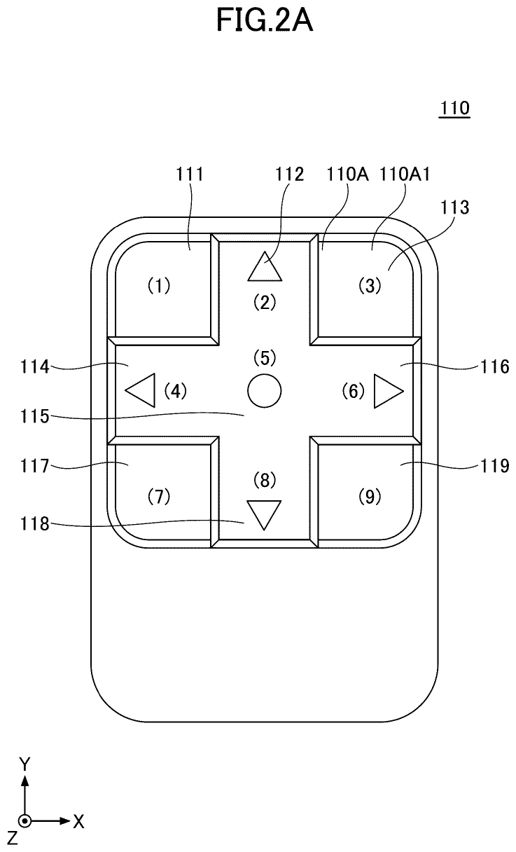

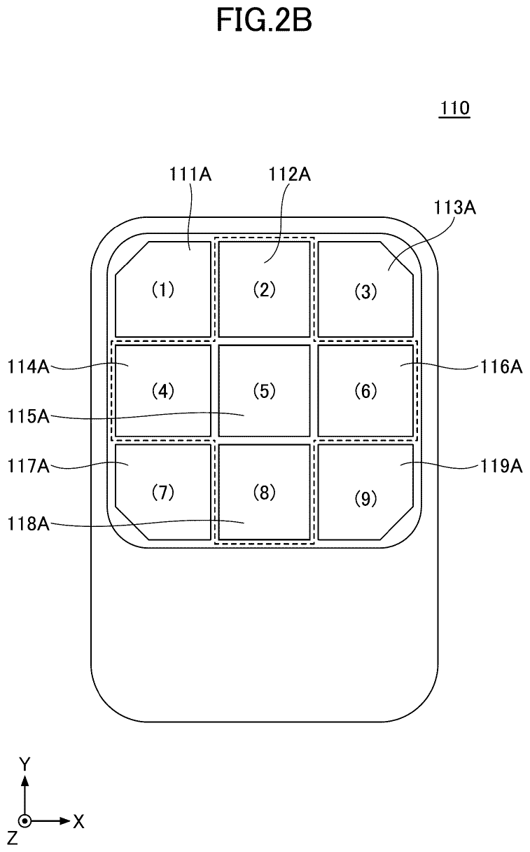

Here, the operation unit 110 will be described with reference to FIGS. 2A and 2B in addition to FIG. 1. FIGS. 2A and 2B are views illustrating an example of the configuration of the operation unit 110. FIG. 2A illustrates a state of the operation unit 110 in which a cover 110A located on the +Z direction side surface of the operation unit 110 is attached. FIG. 2B illustrates a state of the operation unit 110 in which the cover 110A is removed. The +Z direction side surface of the cover 110A is an operation surface 110A1.

### Switches 111 to 119

The switches 111 to 119 include a cover 110A (see FIG. 2A) disposed on the surface of the operation unit 110, and sensor electrodes 111A to 119A (see FIG. 2B) disposed on the back surface side (−Z direction side) of the cover 110A. In the same manner as the switches 111 to 119 of FIG. 2A, the regions in which the sensor electrodes 111A to 119A are disposed, respectively, are denoted by (1) to (9) in FIG. 2B.

As an example, the switches 111 to 119 are substantially arranged into a matrix composed of three rows in the vertical direction and three columns in the horizontal direction. Since the sensor electrodes 111A to 119A are disposed immediately behind the switches 111 to 119, respectively, the sensor electrodes 111A to 119A are substantially arranged into a matrix composed of three rows in the vertical direction and three columns in the horizontal direction, corresponding to the switches 111 to 119, respectively. The sensor electrodes 111A to 119A have substantially the same size as the switches 111 to 119 in plan view.

Here, an embodiment in which the operation unit 110 includes nine switches 111 to 119 and the nine switches 111 to 119 are substantially arranged into a matrix is described. However, the operation unit 110 is not limited to the above embodiment, as long as the operation unit 110 includes a plurality of switches. The number of switches may be any number as long as the number is two or more. Moreover, a plurality of switches may not be substantially arranged into a matrix as long as the switches are arranged adjacent to one another. For example, a plurality of switches may be linearly arranged.

### Sensor Electrodes 111A to 119A

As an example, the sensor electrodes 111A to 119A are electrodes made of a metal foil, a metallic plate, a conductive film, or the like, and are coupled to the control device 120 via wires, cables, or the like. The capacitance between each of the sensor electrodes 111A to 119A and a fingertip FT changes depending on the degree of the proximity (distance) of the fingertip FT to each of the sensor electrodes 111A to 119A, or the dielectric constant of an object interposed between each sensor electrode and the fingertip FT. One example of such an object is gloves that can be worn on hands. The heights of the sensor electrodes 111A to 119A in the Z direction are all equal.

As an example, the cover 110A is integrally formed to cover all of the switches 111 to 119. The operation surface 110A1 of the cover 110A has nine operation regions corresponding to the switches 111 to 119. The nine operation regions are the regions denoted by (1) to (9) in FIG. 2A.

As an example, the operation surface 110A1 of the cover 110A has a configuration in which the heights of the operation regions (2), (4), (5), (6), and (8) in the Z direction are higher than the heights of the operation regions (1), (3), (7), and (9) in the Z direction. When the operation surface 110A1 is divided into nine operation surfaces of the operation regions (1) to (9), respectively, the heights of the operation surfaces in the operation regions (1), (3), (7), and (9) are equal to one another within the operation surface 110A1. Similarly, the heights of the operation surfaces in the operation regions (2), (4), (5), (6), and (8) are equal to one another within the operation surface 110A1.

The operation regions (1), (3), (7), and (9) are an example of a first operation region. The operation surfaces in the operation regions (1), (3), (7), and (9) within the operation surface 110A1 are an example of a first operation surface. The operation regions (2), (4), (5), (6), and (8) are an example of a second operation region. The operation surfaces in the operation regions (2), (4), (5), (6), and (8) within the operation surface 110A1 are an example of a second operation surface.

As described above, as an example, in the cover 110A, the operation surfaces in the operation regions (2), (4), (5), (6), and (8), respectively, are projected in the +Z direction from the operation surfaces in the operation regions (1), (3), (7), and (9), respectively. Specifically, the operation surface 110A1 of the cover 110A has an uneven profile.

The distances between the operation surfaces in the operation regions (2), (4), (5), (6), and (8) and the sensor electrodes 112A, 114A, 115A, 116A, and 118A, respectively, in the Z direction are longer than the distances between the operation surfaces in the operation regions (1), (3), (7), and (9) and the sensor electrodes 111A, 113A, 117A, and 119A, respectively, in the Z direction.

Here, an embodiment in which the cover 110A has the above-described uneven profile is described as an example, but the cover 110A may not have the above-described uneven profile. Specifically, the operation surface 110A1 of the cover 110A may be a flat surface across all of the operation regions (1) to (9).

The operation unit 110 and the control device 120 are coupled to each other via wires, cables, or the like. As an example, the control device 120 is configured integrally with the operation unit 110. Here, an embodiment in which the control device 120 is disposed in the operation unit 110 and is configured integrally with the operation unit 110 is described as an example, but the control device 120 may be configured separately from the operation unit 110.

The control device 120 is coupled to an electronic control unit (ECU) 50 configured to control an electronic device via an in-vehicle network, such as a controller area network (CAN), a local interconnect network (LIN), or the like, mounted in a vehicle. The ECU 50 is an electronic control device configured to control an audio device, a hands-free phone, a cruise control, and other electronic devices of the vehicle. One ECU 50 is illustrated in FIG. 1, but a plurality of ECUs 50 may be coupled to the control device 120. In the case where the electrostatic input device 100 is mounted in an electronic device for something other than a vehicle, instead of the ECU 50, a control device of an electronic device or the like in which the electrostatic input device 100 is mounted is coupled to the control device 120.

### Control Device 120

The control device 120 is implemented by a computer including a memory storing one or more programs and a processor coupled to the memory, such as a central processing unit (CPU), a random access memory (RAM), a read only memory (ROM), an input/output interface, an internal bus, and the like.

The control device 120 includes a main control unit 121, a capacitance detection unit 122, a control unit 123, and a memory 124. The main control unit 121, the capacitance detection unit 122, and the control unit 123 are illustrated as functional blocks for the functions of the program executed by the control device 120. In addition, the memory 124 is a functional representation of the memory of the control device 120.

### Main Control Unit 121

The main control unit 121 is a processing unit that performs overall control processing of the control device 120, and executes processing other than the processing performed by the capacitance detection unit 122 and the control unit 123.

### Capacitance Detection Unit 122

The capacitance detection unit 122 detects the capacitance of the sensor electrodes 111A to 119A, and transmits the data representing the capacitance of each of the sensor electrodes 111A to 119A to the control unit 123. The capacitance of each of the sensor electrodes is a deviation value (ΔAD) obtained by subtracting a reference value from the capacitance (the digital value), which is obtained by digitally converting the capacitance (analog value) of each of the sensor electrodes, and is represented by a count value. The reference value is the capacitance (digital value) in the state in which no operation is performed on the switches 111 to 119.

Hereinafter, the capacitance of each of the sensor electrodes will be referred to as each sensor electrode capacitance, and each sensor electrode capacitance will be described as a deviation value (ΔAD) with respect to the reference value. In each of the sensor electrodes 111A to 119A, one count value representing the deviation (ΔAD) of the capacitance for each of the sensor electrodes 111A to 119A is obtained.

### Control Unit 123

The control unit 123 determines which of the switches 111 to 119 a touch operation is performed on based on the capacitance of each of the sensor electrodes 111A to 119A transmitted from the capacitance detection unit 122. A threshold of capacitance is assigned to each of the sensor electrodes 111A to 119A. The threshold of the capacitance is an example of a capacitance threshold, and is simply referred to as a “threshold Thc” hereinafter. One of the advantages of the electrostatic input device 100 is that only one threshold Thc can be used for assignment to each of the sensor electrodes 111A to 119A. In this case, a capacity of the memory 124 can be reduced compared with the case where a plurality of thresholds are used for each of the sensor electrodes 111A to 119A.

The control unit 123 compares the capacitance of each of the sensor electrodes 111A to 119A with the threshold Thc assigned to each of the sensors, and determine which sensor electrodes (111A to 119A) have the capacitance exceeding the thresholds Thc assigned to the respective sensor electrodes, among the sensor electrodes 111A to 119A.

In the case where only one sensor electrode has a count value exceeding the threshold Thc, the control unit 123 determines that a touch operation has been performed on the above one sensor electrode. The control unit 123 determining the sensor electrode (any of the sensor electrodes 111A to 119A) on which the touch operation has been performed is synonymous with the control unit 123 determining the switch (any of the switches 111 to 119) on which the touch operation has been performed.

In the case where two or more sensor electrodes are determined as having capacitance exceeding the thresholds Thc, respectively, and the determined two or more sensor electrodes are not adjacent to each other, the control unit 123 determines that two or more touch operations have been performed on the determined two or more sensor electrodes, respectively. The two or more touch operations mean touch operations with multiple fingertips FT (multiple touch operations).

Here, a sensor electrode adjacent to a predetermined sensor electrode means that the above sensor electrode is located in the position adjacent to the predetermined sensor electrode in the lateral direction and the longitudinal direction and adjacent to the predetermined sensor electrode in the diagonal direction. Therefore, two or more sensor electrodes being adjacent to each other means that the positional relationship between the sensor electrodes is either being adjacent in the lateral direction and the longitudinal direction or being adjacent in the diagonal direction.

In the case where two or more sensor electrodes are determined as having capacitance exceeding the thresholds Thc, respectively, and the determined two or more sensor electrodes are adjacent to each other, the control unit 123 executes a determination process for highly accurately determining the position of the touch operation. The determination process will be described later.

The determination result of the control unit 123 indicates the sensor electrode on which the touch operation has been performed among the sensor electrodes 111A to 119A. The determination result of the control unit 123 is a detection result of the electrostatic input device 100 detecting which of the sensor electrodes the touch operation has been performed on, and the determination result of the control unit 123 is output to the ECU 50 (see, FIG. 1).

### Memory 124

The memory 124 stores one or more programs, data, or the like necessary for the control device 120 to perform the determination process. In the memory 124, the data representing the capacitance of each of the sensor electrodes 111A to 119A, the data generated by the control unit 123 during the determination process, and the like are stored.

Here, there may be various demands for the sensitivity of the electrostatic input device 100 for detecting a touch operation performed on the switches 111 to 119. For example, in the case where the electrostatic input device 100 is mounted in a vehicle that is designed for use in cold climates, the operation unit 110 may be operated by gloved hands. In such a case, the capacitance of each of the switches 111 to 119 tends to be reduced, and therefore the thresholds Thc in the determination process of the control unit 123 are set to be low. This is to improve the sensitivity for detecting the touch operation performed by the gloved hands. However, when the thresholds Thc are set to be low, as well as the count value obtained from the sensor electrode on which the touch operation has been performed, the count value obtained from the adjacent sensor electrodes may also exceed the thresholds Thc, and therefore some adjustments may be required.

In addition, in the case where the operation surface 110A1 of the cover 110A has an uneven profile as described above, the threshold Thc assigned in the determination process of the control unit 123 is changed between the sensor electrodes 111A, 113A, 117A, and 119A, and the sensor electrodes 112A, 114A, 115A, 116A, and 118A. This is to perform determination of the touch operation performed on the operation regions (1), (3), (7), and (9) and the touch operation performed on the operation regions (2), (4), (5), (6), and (8) with suitable thresholds Thc, respectively. However, in such a case, as well as the count value obtained from the sensor electrode on which the touch operation has been performed, the count values obtained from the adjacent sensor electrodes may also exceed the thresholds Thc, and therefore some adjustments may be required.

Moreover, each of the sensor electrodes 111A to 119A may have a different sensitivity (the degree of change in capacitance) against a touch operation performed with a fingertip FT according to routing of wires connected to the control device 120, a subtle difference in a planar size, or the like. From the above viewpoints, the control unit 123 preferably performs the determination process using the threshold Thc suitable for each of the sensor electrodes 111A to 119A in order to highly accurately determine the touch operation performed on the operation regions (1) to (9). Use of the threshold Thc suitable for each of the sensor electrodes 111A to 119A is also preferable in the case where the operation surface 110A1 of the cover 110A does not have an uneven profile and the entire area of the operation regions (1) to (9) is flat. Use of the threshold Thc suitable for each of the sensor electrodes 111A to 119A is also preferable in the case where the entire operation surface 110A1 is flat and a user performs a touch operation with bare hands, or a user performs a touch operation with gloves on. However, in such cases, as well as the count value obtained from the sensor electrode on which the touch operation has been performed, the count values obtained from the adjacent sensor electrodes may also exceed the thresholds Thc, and therefore some adjustments may be required.

If, as well as the count value obtained from the sensor electrode on which the touch operation has been performed, the count value obtained from the adjacent sensor electrodes also exceed the thresholds Thc, respectively, the position on which the touch operation has been performed cannot be determined, whether it is the sensor electrode, on which the touch operation has been performed, or any of the adjacent sensor electrodes.

### Specific Example of Erroneous Determination

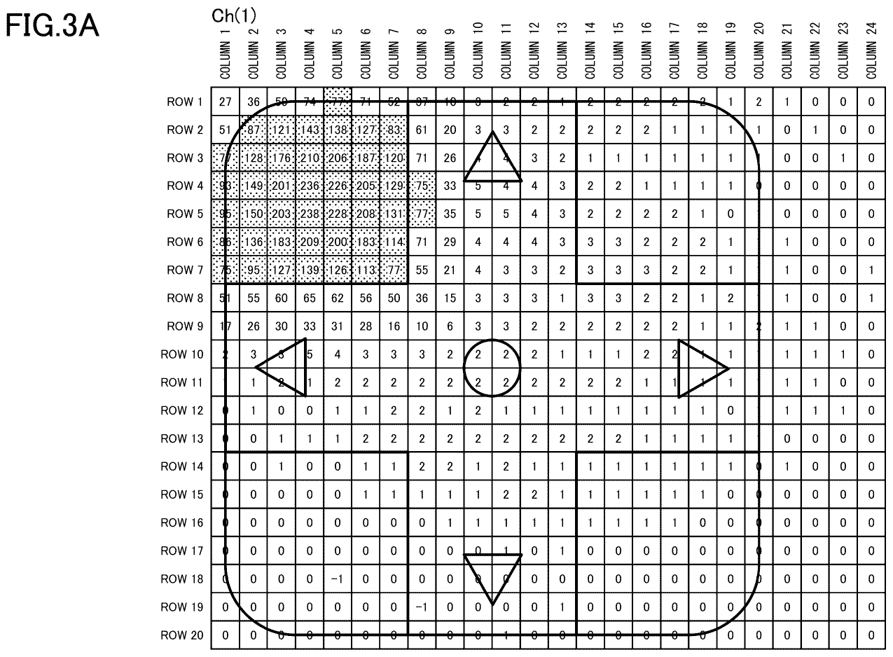

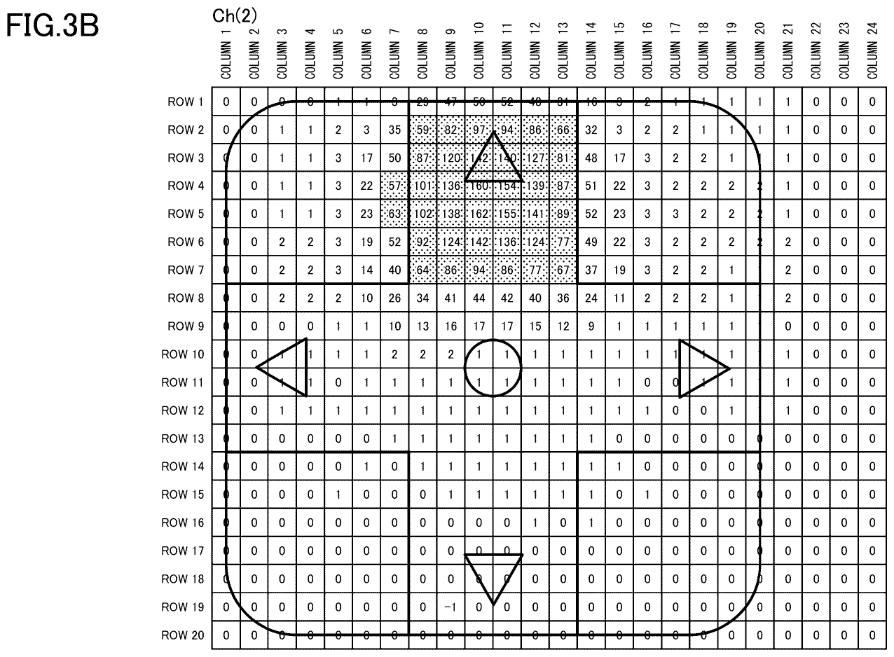

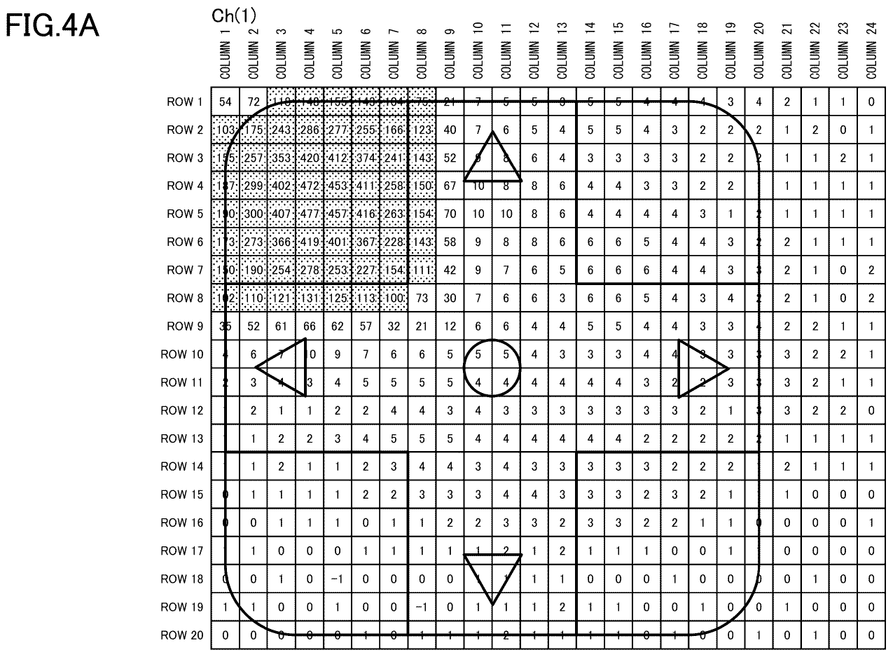

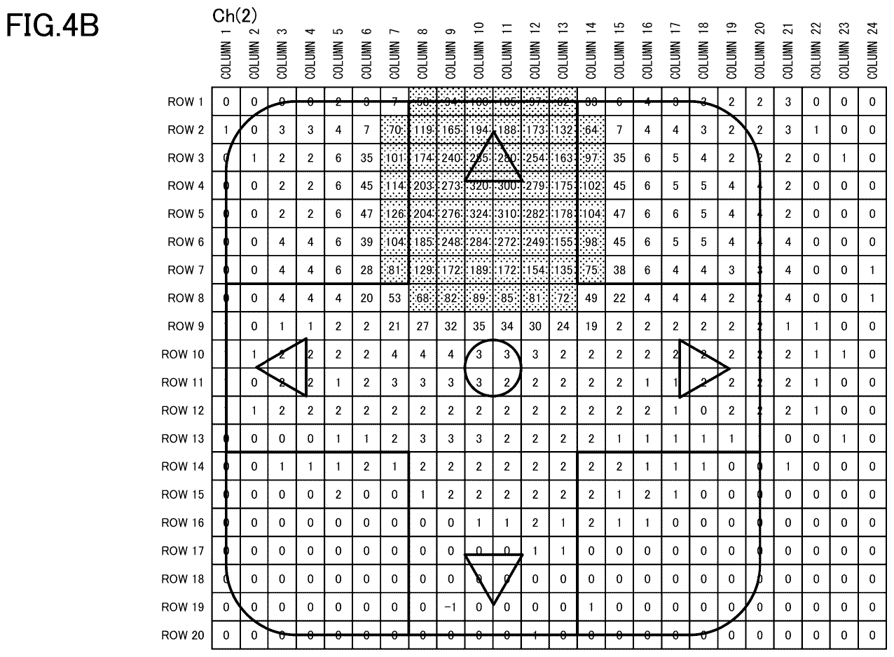

Here, a specific example of erroneous determination that may occur when the electrostatic input device 100 does not execute a determination process that enables highly accurate determination of a position of a touch operation will be described with reference to FIGS. 3A, 3B, 4A, and 4B.

FIGS. 3A and 3B are diagrams illustrating the capacitance distributions of the sensor electrodes 111A and 112A, respectively, when touch operations are performed separately on the switch 111 and the switch 112 by a fingertip FT in the state in which gloves are worn. The capacitance is represented by a count value. In addition, outlines of the switches 111 to 119 are illustrated in FIGS. 3A and 3B.

Here, as an example, capacitance distributions of the sensor electrodes 111A and 112A, in the case where the control unit 123 sets the thresholds Thc of the sensor electrodes 111A to 119A to 75, 55, 80, 60, 70, 60, 80, 65, and 75, respectively, in the determination process, are depicted. These thresholds Thc are values set assuming that a user performs a touch operation with hands wearing gloves. The thresholds Thc used for the sensor electrodes 111A and 112A are 75 and 55, respectively.

Here, the embodiment in which the low thresholds Thc with which the presence or absence of the touch operation can be determined even in the state where the gloves are on the hands is described, but the thresholds Thc may be thresholds Thc that are set assuming that capacitance of a sensor electrode is reduced due to a factor other than gloves.

FIGS. 3A and 3B illustrate, as an example, 480 values of capacitance obtained by dividing a rectangular region including the entire surface of the sensor electrodes 111A to 119A into 480 regions formed by 20 rows in the vertical direction and 24 columns in the horizontal direction at intervals of 3 mm, and performing analysis on the 480 regions. In each of the actual sensor electrodes 111A to 119A, one count value representing the capacitance is obtained. However, in order to more precisely analyze a distribution of capacitance, 480 values of the capacitance obtained by the analysis performed on the 480 regions are presented here. More specifically, FIG. 3A depicts an output of the sensor electrode 111A. The output of the sensor electrode 111A in FIG. 3A is an output of the sensor electrode 111A when a touch operation affects all the 480 regions. Similarly, FIG. 3B depicts an output of the sensor electrode 112A. The output of the sensor electrode 112A in FIG. 3B is an output of the sensor electrode 112A when a touch operation affects all the 480 regions.

In FIG. 3A, when a touch operation affects all the 480 regions, the output of the sensor electrode 111A demonstrates that the capacitance becomes higher in the regions at the centric part of the sensor electrode 111A as the touch operation is performed, and the capacitance becomes lower in the regions away from the centric part of the sensor electrode 111A, as the touch operation is performed. The same applies to the sensor electrode 112A in FIG. 3B.

In FIG. 3A, the regions in which the capacitance exceeds the threshold Thc (75) of the sensor electrode 111A are indicated in grey. Similarly, in FIG. 3B, the regions in which the capacitance exceeds the threshold Thc (55) of the sensor electrode 112A are indicated in grey.

As illustrated in FIG. 3A, when the touch operation affects all the 480 regions, the regions determined as the regions on which the touch operation is performed based on the output of the sensor electrode 111A and the threshold Thc (75) extend outside the sensor electrode 111A to the sensor electrode 112A. Specifically, even if the touch operation is performed on the regions of the sensor electrode 112A adjacent to the sensor electrode 111A within the sensor electrode 112A, the output of the sensor electrode 111A exceeds the threshold Thc (75). Therefore, when the touch operation is performed on the regions of the sensor electrode 112A adjacent to the sensor 111A withing the regions of the sensor electrode 112A, it may be erroneously determined that the touch operation is performed on the sensor electrode 111A.

Similarly, as illustrated in FIG. 3B, when the touch operation affects all of the 480 regions, the regions determined as the regions on which the touch operation is performed based on the output of the sensor electrode 112A and the threshold Thc (55) extend outside the sensor electrode 112A to the sensor electrode 111A. Specifically, even if the touch operation is performed on the regions of the sensor electrode 111A adjacent to the sensor electrode 112A within the sensor electrode 111A, the output of sensor electrode 112A exceeds the threshold Thc (55). Therefore, when the touch operation is performed on the regions of the sensor electrode 111A, it may be erroneously determined that the touch operation is performed on the sensor electrode 112A.

FIGS. 4A and 4B are diagrams illustrating capacitance distributions of the sensor electrodes 111A and 112A when touch operations are separately performed on the switches 111 and 112, respectively, with fingertips FT of bare hands without wearing gloves. As an example, the thresholds Thc, which the control unit 123 uses for the sensor electrodes 111A and 112A in the determination process, are the same values as the thresholds Thc used when the results of FIGS. 3A and 3B are obtained. The capacitance depicted in FIGS. 4A and 4B is capacitance when touch operations are separately performed on the switches 111 and 112, respectively, with a fingertip FT of bare hands without wearing gloves, and is capacitance obtained under the same conditions as the conditions for obtaining the results of FIGS. 3A and 3B, except that the touch operations are performed with bare hands. In addition, outlines of the switches 111 to 119 are illustrated in FIGS. 4A and 4B.

Further, in FIG. 4A, the regions in which the capacitance exceeds the threshold Thc (75) of the sensor electrode 111A are indicated in grey. Similarly, in FIG. 4B, the regions in which the capacitance exceeds the threshold Thc (55) of the sensor electrode 112A are indicated in grey.

As illustrated in FIG. 4A, when the touch operation affects all the 480 regions, the regions determined as regions on which the touch operation is performed based on the output of the sensor electrode 111A and the threshold Thc (75) extend to many more regions outside the sensor electrode 111A compared with FIG. 3A (with gloves on). This is because, in the case of bare hands, the distance between the fingertip FT and the sensor electrode 111A becomes shorter, increasing the capacitance.

More specifically, even if the touch operation is performed on the regions of the sensor electrodes 112A and 114A adjacent to the sensor electrode 111A, the output of the sensor electrode 111A exceeds the threshold Thc (75). Therefore, when the touch operation is performed on the regions of the sensor electrode 112A or 114A, it may be erroneously determined that the touch operation is performed on the sensor electrode 111A.

Similarly, as illustrated in FIG. 4B, when the touch operation affects all the 480 regions, the regions determined as the regions on which the touch operation is performed based on the output of the sensor electrode 112A and the threshold Thc (55) extend to many more regions outside the sensor electrode 112A compared with FIG. 3B (with gloves on). This is because, in the case of bare hands, the distance between the fingertip FT and the sensor electrode 112A becomes shorter, increasing the capacitance.

More specifically, even if the touch operation is performed on the regions of the sensor electrodes 111A, 113A, and 115A adjacent to the sensor electrode 112A within the sensor electrodes 111A, 113A, and 115A, the output of the sensor electrode 112A exceeds the threshold Thc (55). Therefore, when the touch operation is performed on the regions of the sensor electrode 111A, 113A, or 115A, it may be erroneously determined that the touch operation is performed on the sensor electrode 112A.

As illustrated in FIGS. 3A, 3B, 4A, and 4B, if the electrostatic input device 100 does not execute a determination process capable of highly accurately determining a position of a touch operation, when a touch operation is performed on regions of any of the sensor electrodes, it may be erroneously determined that a touch operation is performed on a sensor electrode adjacent the sensor electrode on which the touch operation has been performed. Although the erroneous determination of the regions of the sensor electrodes 111A and 112A have been described, the same applies to the case where a touch region is performed in the regions of the sensor electrodes 113A to 119A.

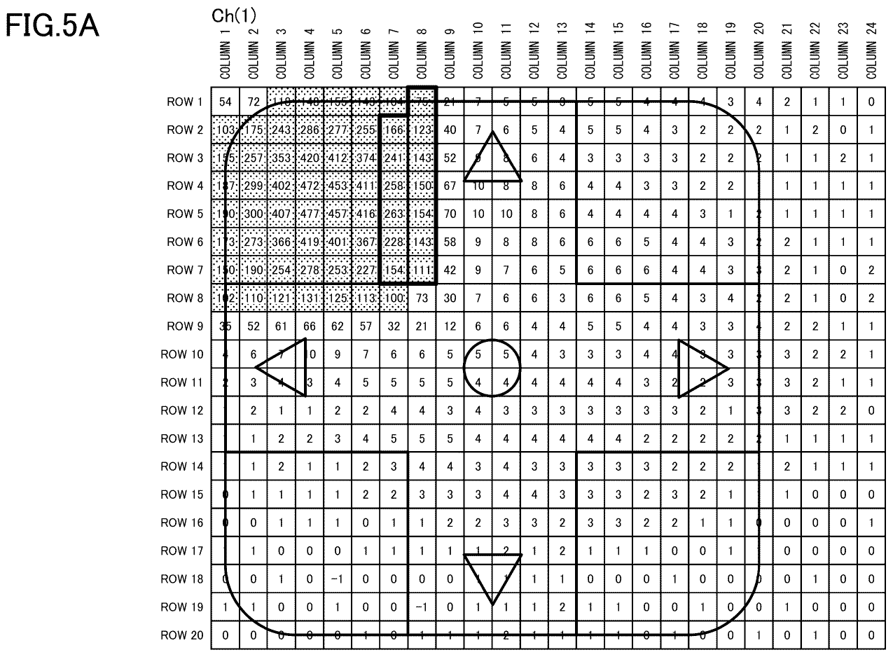

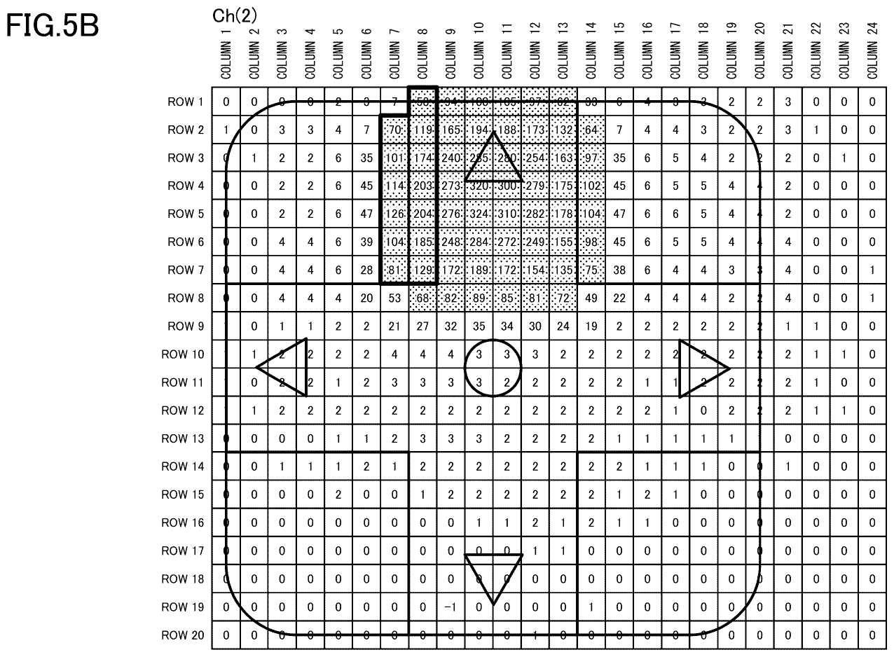

FIG. 5A is a diagram illustrating an overlapping area of the regions in which the capacitance exceeds the thresholds in the capacitance distributions of the sensor electrodes of FIGS. 4A and 4B. FIG. 5B is a diagram illustrating an overlapping area of the capacitance distributions of the sensor electrodes 111A and 112A of FIGS. 4A and 4B. In FIG. 5A, the region also indicated in grey in FIG. 4B within the region indicated in grey in FIG. 4A is surrounded by a thick line. Similarly, in FIG. 5B, the region also indicated in grey in FIG. 4A within the region indicated in grey in FIG. 4B is surrounded by a thick line. The region surrounded by the thick line in each of FIGS. 5A and 5B is composed of 13 regions in total, which include 6 regions at the second to seventh rows of the seventh column, and 7 regions at the first to seventh rows of the eighth column.

The seven regions at the first to seventh rows of the eighth column illustrated in FIG. 5A are located within the regions of the sensor electrode 112A, but are regions in which the capacitance generated due to the output of the sensor electrode 111A exceeds the threshold Thc (75) as the center of the fingertip FT is positioned thereon. This is because, when the center of the fingertip FT is positioned in the seven regions at the first to seventh rows of the eighth column, the capacitance in the seven regions generated due to the output of the sensor electrode 111A is 75, 123, 143, 150, 154, 143, and 111, respectively. Therefore, even when a touch operation is performed on the sensor electrode 112A, the capacitance of the sensor electrode 111A exceeds the threshold Thc (75) as the center of the fingertip FT is positioned in the seven regions at the first to seventh rows of the eighth column illustrated in FIG. 5A, leading to erroneous determination.

The six regions at the second to seventh rows of the seventh column illustrated in FIG. 5B are located within the regions of the sensor electrode 111A, but are regions in which the capacitance generated due to the output of the sensor electrode 112A exceeds the threshold Thc (55) as the center of the fingertip FT is positioned thereon. This is because, when the center of the fingertip FT is positioned in the six regions at the second to seventh rows of the seventh column, the capacitance of the sensor electrode 112A in the six regions is 70, 101, 114, 126, 104, and 81, respectively. Therefore, even when a touch operation is performed on the sensor electrode 111A, the capacitance of the sensor electrode 112A exceeds the threshold Thc (55) as the center of the fingertip FT is positioned in the six regions at the second to seventh rows of the seventh column in FIG. 5B, leading to erroneous determination.

Specifically, in the determination performed on the sensor electrodes 111A and 112A, it cannot be determined whether a touch operation is performed on the sensor electrode 111A or the sensor electrode 112A, if the center of the fingertip FT is positioned in the six regions at the second to seventh rows of the seventh column or the seven regions at the first to seventh rows of the eighth column.

### Process of Highly Accurately Determining Position of Touch Operation

Hereinafter, a process that the electrostatic input device 100 executes for enabling highly accurate determination of a sensor electrode to which a touch operation has been performed will be described.

The control unit 123 determines a sensor electrode to which a touch operation has been performed, when there are two or more sensor electrodes as having capacitance exceeding thresholds Thc, respectively, and the two or more sensor electrodes are adjacent to each other. The control unit 123 identifies the sensor electrode to which the touch operation has been performed among the determined two or more sensor electrodes based on a ratio of capacitance of each determined sensor electrode and the threshold Thc assigned to each determined sensor electrode. The ratio of the capacitance of each determined sensor electrode to the threshold Thc assigned to each determined sensor electrode is an example of a ratio between capacitance of each of the two or more sensor electrodes and the capacitance threshold assigned to the corresponding sensor electrode.

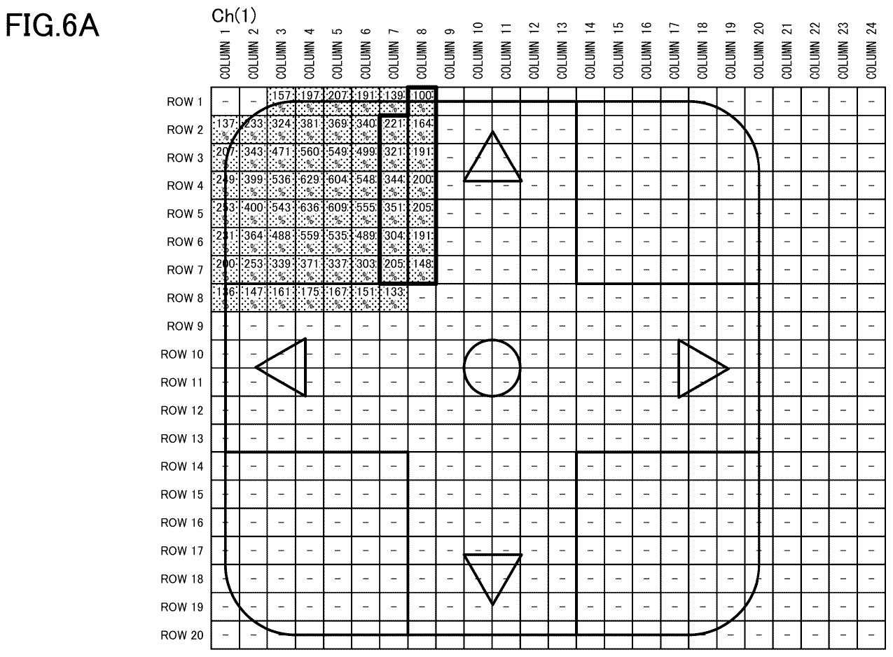

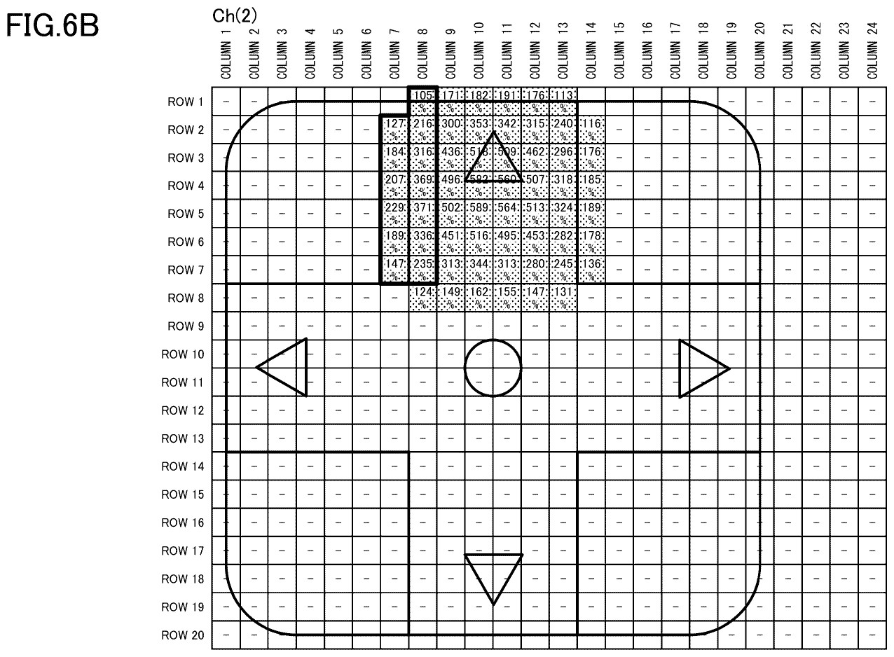

FIG. 6A is a diagram depicting the ratio of the capacitance (count value) illustrated in FIG. 5A to the threshold Thc of the sensor electrode 111A in percentage (%). This ratio is obtained, as an example, by dividing the capacitance (count value) illustrated in FIG. 5A by the threshold Thc of the sensor electrode 111A. FIG. 6B is a diagram depicting the ratio of the capacitance (count value) illustrated in FIG. 5B to the threshold Thc of the sensor electrode 112A in percentage (%). This ratio is obtained, as an example, by dividing the capacitance (count value) illustrated in FIG. 5B by the threshold Thc of the sensor electrode 112A.

The quotient obtained by dividing the capacitance of each region in FIG. 5A by the threshold Thc of the sensor electrode 111A is the ratio of the capacitance obtained in each region due to the sensor electrode 111A to the threshold Thc of the sensor electrode 111A. Similarly, the quotient obtained by dividing the capacitance of each region in FIG. 5B by the threshold Thc of the sensor electrode 112A is the ratio of the capacitance obtained in each region due to the sensor electrode 112A to the threshold Thc of the sensor electrode 112A.

As a fingertip FT comes closer to a sensor electrode, the capacitance of the sensor electrode increases. Specifically, a large ratio of the capacitance to the threshold Thc assigned to the sensor electrode means that the fingertip FT is approaching the sensor electrode. When two or more sensor electrodes are determined as having capacitance exceeding the thresholds Thc and the determined two or more sensor electrodes are adjacent to each other, it can therefore be assumed that, as the ratio of the capacitance to the threshold Thc assigned to the sensor electrode is larger, the fingertip is closer to such a sensor electrode so that a touch operation is performed on such a sensor electrode.

For the above reason, the control unit 123 determines that the sensor electrode having the largest ratio is the sensor electrode on which the touch operation has been performed, among the two or more sensor electrodes being determined as having capacitance exceeding the thresholds Thc. Specifically, in the case where three or more sensor electrodes are determined as having capacitance exceeding the thresholds Thc, the control unit 123 determines that the sensor electrode having the largest ratio is the sensor electrode on which the operation input has been performed. In the case where two sensor electrodes are determined as having capacitance exceeding the thresholds Thc, the control unit 123 determines that the sensor electrode having the larger ratio is the sensor electrode on which the operation input has been performed.

In FIG. 6A, the ratios obtained from the capacitance of the sensor electrode 111A in the six regions at the second to seventh rows of the seventh column are 221%, 321%, 344%, 351%, 304%, and 205%, respectively. In FIG. 6B, the ratios obtained from the capacitance of the sensor electrode 112A in the six regions at the second to seventh rows of the seventh column are 127%, 184%, 207%, 229%, 189%, and 147%, respectively. When the ratios of the same regions at the same column and the same row are compared, all the ratios obtained in the six regions at the second to seventh rows of the seventh column illustrated in FIG. 6A are larger than the ratios obtained in the six regions at the second to seventh rows of the seventh column illustrated in FIG. 6B.

In FIG. 6A, the ratios obtained from the capacitance of the sensor electrode 111A in the seven regions at the first to seventh rows of the eighth column are 100%, 164%, 191%, 200%, 205%, 191%, and 148%, respectively. In FIG. 6B, the ratios obtained from the capacitance of the sensor electrode 112A in the seven regions at the first to seventh rows of the eighth 8 column are 105%, 216%, 316%, 369%, 371%, 336%, and 235%, respectively. When the ratios of the same regions at the same column and the same row are compared, all the ratios obtained in the seven regions at the first to seventh rows of the eighth column illustrated in FIG. 6B are larger than the ratios obtained in the seven regions at the first to seventh rows of the eighth column illustrated in FIG. 6A.

In the above manner, in the case where two or more sensor electrodes are determined as having capacitance exceeding the thresholds Thc assigned to the sensor electrodes, respectively, the control unit 123 determines that the sensor electrode having the largest ratio is the sensor electrode on which the operation input has been performed, among the ratios obtained for the two or more sensor electrodes as having capacitance exceeding the thresholds Thc.

Specifically, when a touch operation is performed so that the center of the fingertip FT is located in the region at the second row of the seventh column, the ratio obtained from the capacitance of the sensor electrode 111A becomes 221%, the ratio obtained from the capacitance of the sensor electrode 112A becomes 127%, and therefore the control unit 123 determines that the touch operation has been performed on the sensor electrode 111A.

Similarly, when a touch operation is performed so that the center of the fingertip FT is located in the region at the third row of the seventh column, the ratio obtained from the capacitance of the sensor electrode 111A becomes 321%, the ratio obtained from the capacitance of the sensor electrode 112A becomes 184%, and therefore the control unit 123 determines that the touch operation has been performed on the sensor electrode 111A.

When a touch operation is performed so that the center of the fingertip FT is located in the region at the fourth row of the seventh column, the ratio obtained from the capacitance of the sensor electrode 111A becomes 344%, the ratio obtained from the capacitance of the sensor electrode 112A becomes 207%, and therefore the control unit 123 determines that the touch operation has been performed on the sensor electrode 111A.

When a touch operation is performed so that the center of the fingertip FT is located in the region at the fifth row of the seventh column, the ratio obtained from the capacitance of the sensor electrode 111A becomes 351%, the ratio obtained from the capacitance of the sensor electrode 112A becomes 229%, and therefore the control unit 123 determines that the touch operation has been performed on the sensor electrode 111A.

When a touch operation is performed so that the center of the fingertip FT is located in the region at the sixth row of the seventh column, the ratio obtained from the capacitance of the sensor electrode 111A becomes 304%, the ratio obtained from the capacitance of the sensor electrode 112A becomes 189%, and therefore the control unit 123 determines that the touch operation has been performed on the sensor electrode 111A.

When a touch operation is performed so that the center of the fingertip FT is located in the region at the seventh row of the seventh column, the ratio obtained from the capacitance of the sensor electrode 111A becomes 205%, the ratio obtained from the capacitance of the sensor electrode 112A becomes 147%, and therefore the control unit 123 determines that the touch operation has been performed on the sensor electrode 111A.

When a touch operation is performed so that the center of the fingertip FT is located in the region at the first row of the eighth column, the ratio obtained from the capacitance of the sensor electrode 111A becomes 100%, the ratio obtained from the capacitance of the sensor electrode 112A becomes 105%, and therefore the control unit 123 determines that the touch operation has been performed on the sensor electrode 112A.

When a touch operation is performed so that the center of the fingertip FT is located in the region at the second row of the eighth column, the ratio obtained from the capacitance of the sensor electrode 111A becomes 164%, the ratio obtained from the capacitance of the sensor electrode 112A becomes 216%, and therefore the control unit 123 determines that the touch operation has been performed on the sensor electrode 112A.

When a touch operation is performed so that the center of the fingertip FT is located in the region at the third row of the eighth column, the ratio obtained from the capacitance of the sensor electrode 111A becomes 191%, the ratio obtained from the capacitance of the sensor electrode 112A becomes 316%, and therefore the control unit 123 determines that the touch operation has been performed on the sensor electrode 112A.

When a touch operation is performed so that the center of the fingertip FT is located in the region at the fourth row of the eighth column, the ratio obtained from the capacitance of the sensor electrode 111A becomes 200%, the ratio obtained from the capacitance of the sensor electrode 112A becomes 369%, and therefore the control unit 123 determines that the touch operation has been performed on the sensor electrode 112A.

When a touch operation is performed so that the center of the fingertip FT is located in the region at the fifth row of the eighth column, the ratio obtained from the capacitance of the sensor electrode 111A becomes 205%, the ratio obtained from the capacitance of the sensor electrode 112A becomes 371%, and therefore the control unit 123 determines that the touch operation has been performed on the sensor electrode 112A.

When a touch operation is performed so that the center of the fingertip FT is located in the region at the sixth row of the eighth column, the ratio obtained from the capacitance of the sensor electrode 111A becomes 191%, the ratio obtained from the capacitance of the sensor electrode 112A becomes 336%, and therefore the control unit 123 determines that the touch operation has been performed on the sensor electrode 112A.

When a touch operation is performed so that the center of the fingertip FT is located in the region at the seventh row of the eighth column, the ratio obtained from the capacitance of the sensor electrode 111A becomes 148%, the ratio obtained from the capacitance of the sensor electrode 112A becomes 235%, and therefore the control unit 123 determines that the touch operation has been performed on the sensor electrode 112A.

Here, the description has been given through the embodiment in which, when the count values of the capacitance of the sensor electrodes 111A and 112A exceed both thresholds Thc of the sensor electrodes 111A and 112A at the boundary between the sensor electrodes 111A and 112A, the determination is performed to identify which of the sensor electrodes 111A and 112A the touch operation has been performed on. However, the same applies to the boundary between any one of the sensor electrodes 111A to 119A and the sensor electrodes adjacent to the one of the sensor electrodes.

The description has been given above on the embodiment in which, when there are two or more sensor electrodes having capacitance exceeding the thresholds Thc assigned to the sensor electrodes, respectively, the control unit 123 determines that the sensor electrode having the largest ratio is the sensor electrode on which the operation input has been performed, among the ratios obtained for the two or more sensor electrodes as having capacitance exceeding the thresholds Thc. The ratio is a ratio of the capacitance of the sensor electrode, which is determined by the control unit 123 as having capacitance exceeding the threshold Thc assigned to the sensor electrode, to the threshold Thc of the sensor electrode. Such a ratio can be obtained, as an example, by dividing the capacitance of the sensor electrode by the threshold Thc of the sensor electrode.

However, such a ratio may be obtained by multiplying the capacitance by the reciprocal of the threshold Thc.

Instead of the ratio described above, a value obtained by dividing the quotient by the threshold Thc of the sensor electrode one time or multiple times may be used. The above quotient is obtained by dividing the capacitance of the sensor electrode, which is determined by the control unit 123 as having capacitance exceeding the threshold Thc assigned to the sensor electrode, by the threshold Thc of the sensor electrode. This is because, similarly to the quotient, the value obtained by dividing the quotient by the threshold Thc of the sensor electrode one time or multiple times becomes larger for the closer sensor electrode. In this manner, determination of the sensor electrode on which the operation input has been performed using based on the value obtained by dividing the quotient by the threshold Thc of the sensor electrode one time or multiple times is one embodiment for identifying the sensor electrode on which the operation input is performed based on the above-described ratio.

Moreover, the control unit 123 may calculate the reciprocal of the above ratio, and may determine that the sensor electrode having the smallest reciprocal (inverse ratio) is the sensor electrode on which the operation input has been performed. Such a reciprocal is a ratio of the threshold Thc of the sensor electrode to the capacitance of the sensor electrode determined by the control unit 123 as having capacitance exceeding the threshold Thc assigned to the sensor electrode. Moreover, the reciprocal may be determined by multiplying the reciprocal of the capacitance by the threshold Thc.

### Flowchart

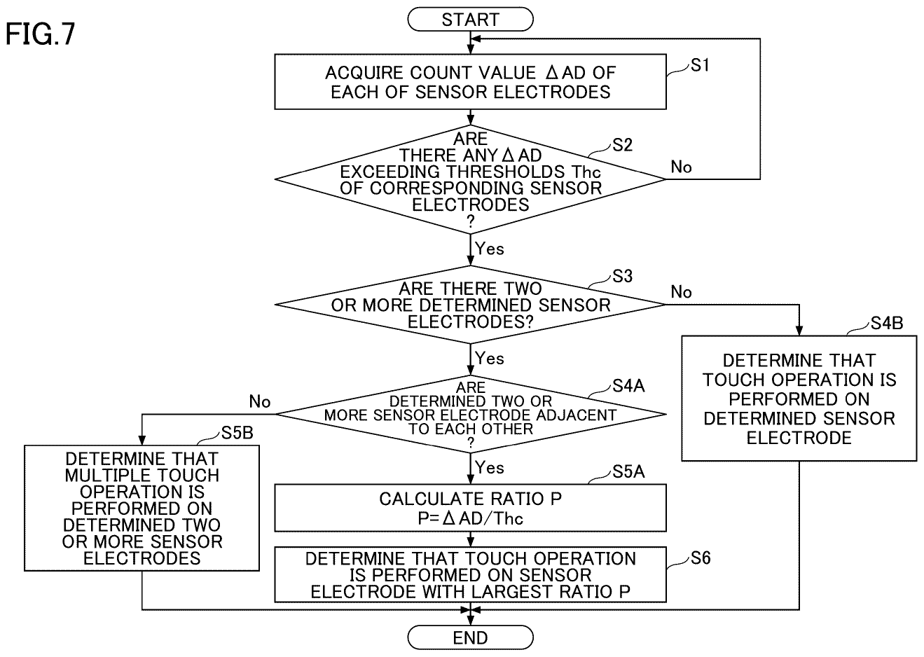

FIG. 7 is a diagram illustrating an example of a determination process executed by the control unit 123.

The control unit 123 acquires a count value ΔAD of each of the sensor electrodes 111A to 119A (step S1).

The control unit 123 compares each ΔAD with a threshold Thc of a corresponding sensor electrode 111A, and determines whether there are any ΔAD exceeding the threshold Thc (step S2). The threshold Thc of the sensor electrode 111A is a threshold Thc assigned to the sensor electrode on which the ΔAD is acquired. By the process of step S2, each sensor electrode with ΔAD exceeding the threshold Thc assigned to the corresponding sensor electrode is determined.

When the control unit 123 determines that there is no ΔAD exceeding the threshold Thc (S2: No), the control unit 123 returns the flow of the processes back to step S1.

When the control unit 123 determines that there is ΔAD exceeding the threshold Thc (S2: Yes), the control unit 123 determines whether the number of the sensor electrodes determined at step S2 is two or more (step S3).

When the control unit 123 determines that the sensor electrodes determined at S2 include two or more sensor electrodes (S3: Yes), the control unit 123 determines whether or not the two or more sensor electrodes are adjacent to each other (step S4A).

When the control unit 123 determines that the two or more sensor electrodes are adjacent to each other (S4A: Yes), the control unit 123 calculates a ratio P using ΔAD of each of the two or more sensor electrodes and the threshold Thc assigned to the corresponding sensor electrode according to the following equation (1) (step S5A).

$$P = Δ AD / Thc \qquad ( 1 )$$

The control unit 123 determines, among a plurality of ratios P determined at step S5, that the sensor electrode having the largest ratio P is the sensor electrode on which the touch operation has been performed (step S6). Once the process of step S6 is completed, the control unit 123 ends the series of processes.

When the control unit 123 determines at step S3 that the number of the sensor electrodes determined at S2 is not two or more (S3: No), the control unit 123 determines that the touch operation has been performed on the determined sensor electrode (step S4B). The flow proceeds to step S4B when there is only one sensor electrode having ΔAD exceeding the threshold Thc. Once the process of step S4B is completed, the control unit 123 ends the series of processes.

When the control unit 123 determines that the determined two or more sensor electrodes are not adjacent to each other at S4A (S4A: No), the control unit 123 determines that multiple touch operations have been performed on the determined two or more sensor electrodes (step S5B). For example, this corresponds to the case where multiple touch operations have been performed on two or more sensor electrodes with another sensor electrode being interposed therebetween, such as the sensor electrodes 111A and 113A, by multiple fingertips FT. Once the process of step S5B is completed, the control unit 123 ends the series of processes.

The control unit 123 repeatedly executes the series of processes from the start to the end while the power supply of the electrostatic input device 100 is turned on.

### Effects

The electrostatic input device 100 includes a plurality of sensor electrodes 111A to 119A disposed to correspond to a plurality of operation regions ((1) to (9)) on an operation surface 110A1 on which an operation input is performed. The electrostatic input device 100 includes a control unit 123 that is configured to compare thresholds Thc, which are assigned to the plurality of sensor electrodes 111A to 119A, respectively, with capacitance of the plurality of sensor electrodes 111A to 119A, respectively, and determine one or more sensor electrodes having the capacitance exceeding the assigned thresholds Thc. When the one or more sensor electrodes having the capacitance exceeding the assigned thresholds Thc include two or more sensor electrodes and the two or more sensor electrodes are adjacent to each other, the control unit 123 is configured to identify, among the two or more sensor electrodes, the sensor electrode on which the operation input is performed based on a ratio between the capacitance of each of the determined two or more sensor electrodes and the assigned threshold Thc. Therefore, even when capacitance of both of the adjacent sensor electrodes exceeds the corresponding thresholds Thc, which of the sensor electrodes the operation input has been performed on can be highly accurately determined based on the calculated values.

Accordingly, there can be provided the electrostatic input device 100 capable of highly accurately determining a position of an operation input.

When the one or more sensor electrodes having capacitance exceeding the assigned thresholds Thc include one sensor electrode, the control unit 123 may be configured to determine that an operation input has been performed on the one sensor electrode. In the case where there is one sensor electrode having the capacitance exceeding the threshold Thc assigned to the corresponding sensor electrode, it is confirmed that the operation input has been performed on the one sensor electrode, and therefore the sensor electrode on which the operation input has been performed can be promptly identified.

When the one or more sensor electrodes having the capacitance exceeding the capacitance threshold include two or more sensor electrodes and the two or more sensor electrodes are not adjacent to each other, the control unit 123 may be configured to determine that multiple operation inputs are performed on the two or more sensor electrodes, respectively. In the case where the two or more sensor electrodes are not adjacent to each other, it can be determined that multiple touch operations have been performed.

The ratio is a ratio of the capacitance of each of the one or more sensor electrodes to the assigned capacitance threshold Thc, and the control unit 123 may be configured to identify, when the one or more sensor electrodes having the capacitance exceeding the capacitance threshold include two or more sensor electrodes, that the sensor electrode having the largest ratio is a sensor electrode on which the operation input has been performed, among the ratios obtained for the determined two or more sensor electrodes. Since the ratio of the capacitance of the determined sensor electrode to the assigned capacitance threshold Thc can be easily calculated, and the sensor electrode having the largest ratio can be determined as the sensor electrode on which the operation input is performed, the electrostatic input device 100 capable of highly accurately determining the position of the operation input can be provided.

Further, the ratio is a ratio of the assigned capacitance threshold Thc to the capacitance of each of the one or more sensor electrodes, and the control unit 123 may be configured to identify, when the one or more sensor electrodes having the capacitance exceeding the capacitance threshold include two or more sensor electrodes, that the sensor electrode having the smallest ratio is the sensor electrode on which the operation input has been performed, among the ratios obtained for the determined two or more sensor electrodes. Since the ratio of the threshold Thc to the capacitance of the determined sensor electrode can be easily calculated, and the sensor electrode having the smallest ratio can be determined as the sensor electrode on which the operation input is performed, the electrostatic input device 100 capable of highly accurately determining the position of the operation input can be provided.

Further, the operation surface 110A1 includes a first operation surface in a first operation region among the plurality of operation regions ((1) to (9)) and a second operation surface in a second operation region among the plurality of operation regions ((1) to (9)). A first distance between the first operation surface and the sensor electrode corresponding to the first operation region may be shorter than a second distance between the second operation surface and the sensor electrode corresponding to the second operation region. Even when the operation surface 110A1 has an uneven profile and the heights of the first operation surface and the second operation surface are different, which of the sensor electrodes the operation input has been performed on can be highly accurately determined based on the calculated values calculated using the appropriately set thresholds Thc.

Accordingly, even when the operation surface 110A1 has an uneven profile and the heights of the first operation surface and the second operation surface are different, the electrostatic input device 100 capable of highly accurately determining the position of the operation input can be provided.

Although the electrostatic input device of the exemplary embodiment of the present invention has been described above, the present invention is not limited to the specifically disclosed embodiment, and various modification and changes can be made without departing from the scope of the claims.

What is claimed is:

1. An electrostatic input device, comprising:
a plurality of sensor electrodes disposed corresponding to a plurality of operation regions on an operation surface on which an operation input is performed; and
a computer including a memory storing one or more programs and a processor coupled to the memory, the computer being configured to compare a plurality of capacitance thresholds, which are assigned to the plurality of sensor electrodes, respectively, with capacitance of the plurality of sensor electrodes, respectively, and check one or more sensor electrodes having the capacitance exceeding the capacitance threshold assigned to a corresponding sensor electrode,
wherein, the computer is configured to, when the one or more sensor electrodes having the capacitance exceeding the capacitance threshold assigned to the corresponding sensor electrode include two or more sensor electrodes and the two or more sensor electrodes are adjacent to each other, identify, among the two or more sensor electrodes, the sensor electrode on which the operation input is performed based on a ratio between the capacitance of each of the two or more sensor electrodes and the capacitance threshold assigned to the corresponding sensor electrode.

2. The electrostatic input device according to claim 1,
wherein, when the one or more sensor electrodes having the capacitance exceeding the capacitance threshold assigned to the corresponding sensor electrode include one sensor electrode, the computer is configured to determine that an operation input is performed on the one sensor electrode.

3. The electrostatic input device according to claim 1,
wherein, when the one or more sensor electrodes having the capacitance exceeding the capacitance threshold assigned to the corresponding sensor electrode include two or more sensor electrodes and the two or more sensor electrodes are not adjacent to each other, the computer is configured to determine that multiple operation inputs are performed on the two or more sensor electrodes, respectively.

4. The electrostatic input device according to claim 1,
wherein the ratio is a ratio of the capacitance of each of the one or more sensor electrodes to the capacitance threshold assigned to the corresponding sensor electrode, and
the computer is configured to, when the one or more sensor electrodes having the capacitance exceeding the capacitance threshold assigned to the corresponding sensor electrode include two or more sensor electrodes, identify the sensor electrode having the largest ratio, among ratios obtained for the two or more electrodes, as the sensor electrode on which the operation input is performed.

5. The electrostatic input device according to claim 1,
wherein the ratio is a ratio of the capacitance threshold assigned to the corresponding sensor electrode to the capacitance of each of the detected one or more sensor electrodes, and
the computer is configured to, when the one or more sensor electrodes having the capacitance exceeding the capacitance threshold assigned to the corresponding sensor electrode include two or more sensor electrodes, identify the sensor electrode having the smallest ratio among ratios obtained for the two or more electrodes, as the sensor electrode on which the operation input is performed.

6. The electrostatic input device according to claim 1,
wherein the operation surface includes a first operation surface in a first operation region among the plurality of operation regions, and a second operation surface in a second operation region among the plurality of operation regions, and
a first distance between the first operation surface and the sensor electrode corresponding to the first operation region is shorter than a second distance between the second operation surface and the sensor electrode corresponding to the second operation region.
